(19) United States
(12) Patent Application Publication
(10) Pub. No.: US 2004/0103504 A1
(43) Pub. Date: Jun. 3, 2004

(54) Fastener for a CPU radiator

(76) Inventor: Jen-Cheng Lin, Chung-Ho City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/290,172

(22) Filed: Nov. 8, 2002

(51) Int. Cl. H05K 7/20

(52) U.S. Cl. 24/458

(57) ABSTRACT

A fastener for installing a radiator on a radiator seat is disclosed. The fastener has a strip having a central portion curved downwards from two ends thereof. A first attaching portion is formed at a first end of the strip. The first attaching portion has a first hook formed at a bottom thereof. A second attaching portion is formed at a second end of the strip. The second attaching portion has a second hook formed at a bottom thereof and a tab formed on a top of thereof.

### BACKGROUND OF THE INVENTION

1. Field of the Invention

The present invention is related to a CPU radiator, and more particularly to a fastener for the CPU radiator.

2. Description of Related Art

Radiators are mounted on seats on CPUs to lower the temperature of the CPU while it is operating. Intel Corporation has presented a radiator seat with a standard specification used for the Pentium® 4 CPU. However, conventional fasteners for radiators are not specially designed for the radiator seat.

Therefore, the invention provides a fastener to mitigate and/or obviate the aforementioned problem.

### SUMMARY OF THE INVENTION

The main objective of the invention is to provide a fastener with which it is easy to install a radiator on a seat on a CPU.

Other objects, advantages and novel features of the invention will become more apparent from the following detailed description when taken in conjunction with the accompanying drawings.

### BRIEF DESCRIPTION OF THE DRAWINGS

FIG. 1 is an exploded perspective view of a radiator seat, a radiator and fasteners in accordance with the invention;

FIG. 2 is a perspective view showing that the radiator is installed on the radiator seat by the fasteners in accordance with the invention;

FIG. 3 is a side view of the components shown in FIG. 2;

FIG. 4 is a sectional view of FIG. 2 along the line “4-4”;

FIG. 5 is a perspective view of a second embodiment in accordance with the invention; and

FIG. 6 is a sectional view showing that a radiator is installed on a seat by the fasteners in FIG. 5.

### DETAILED DESCRIPTION OF THE PREFERRED EMBODIMENT

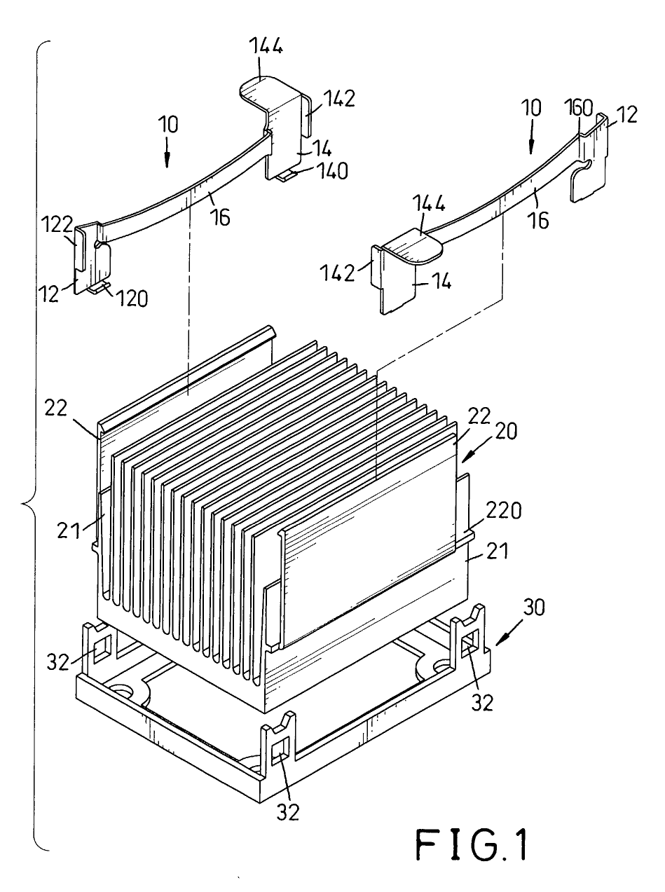

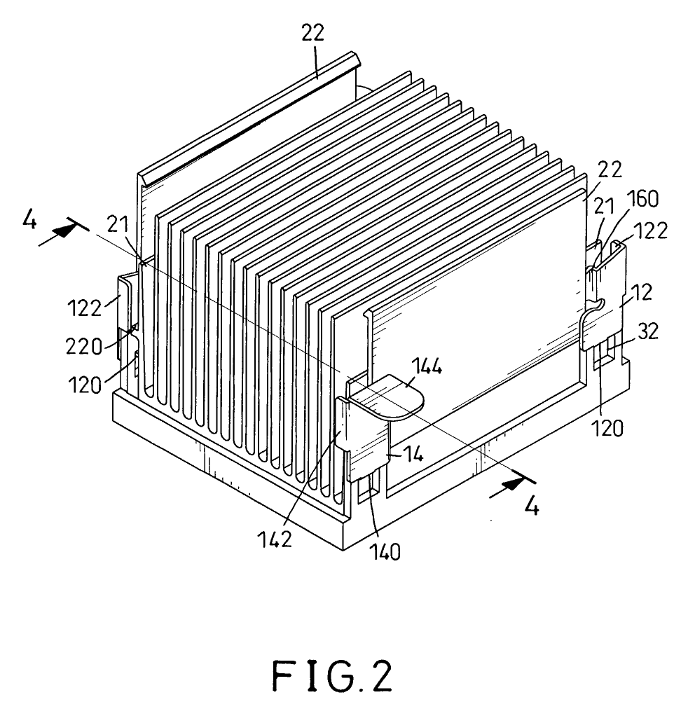

Referring to FIGS. 1 and 2, a radiator (20) is installed on a radiator seat (30) by two fasteners (10) in accordance with the invention.

The radiator (20) has a plurality of fins (not numbered) formed thereon and two side fins (21) respectively formed at two sides thereof. Two wings (22) are respectively formed on the side fins (21) and extend upwards. Two slots (220) are respectively defined between the side fins (21) and the wings (22).

The radiator seat (30) has four apertures (32) respectively defined at four corners thereof. The radiator (20) is received in the radiator seat (30), and the wings (22) are located between the respective apertures (32).

The fastener (10) has a strip (16), a first attaching portion (12) formed at a first end of the strip (16), and a second attaching portion (14) formed at a second end of the strip (16). The first attaching portion (12) has a first hook (120) formed at a bottom thereof, and a first ear (122) formed at a side thereof. The second attaching portion (14) has a second hook (140) formed at a bottom thereof, and a second ear (142) formed at a side thereof. A tab (144) is formed on a top of the second attaching portion (14).

The strip (16) has a central portion (not numbered) curved downwards from the ends thereof. Two bent parts (160) are respectively formed at joints between the strip (16) and the attaching portions (12, 14).

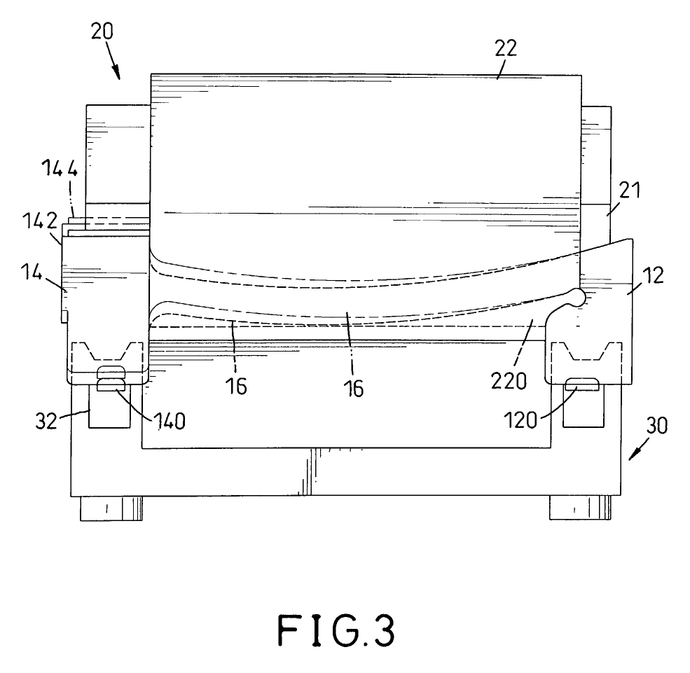

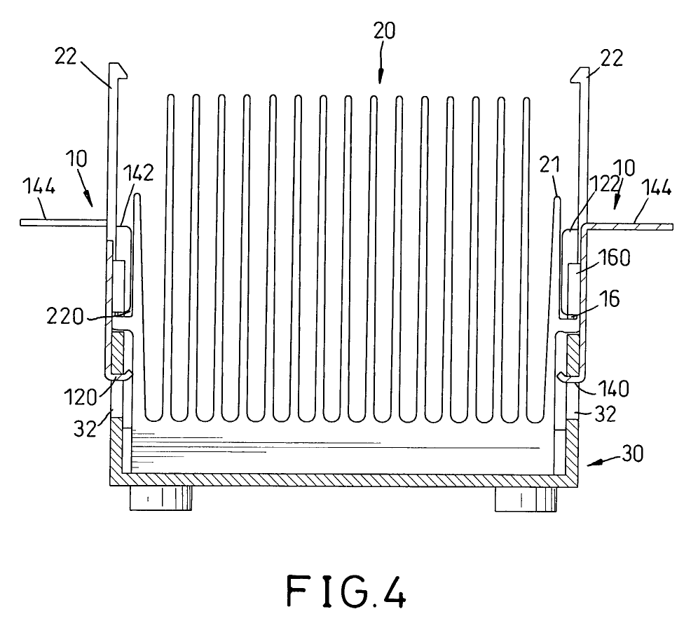

Referring to FIGS. 3 and 4, the radiator (20) is first placed on the seat (30). The first hook (120) of the first attaching portion (12) of the fastener (10) is attached in the corresponding aperture (32) and the first ear (122) is abutted the radiator (20). The strip (16) is located in the slot (220), and the second hook (140) of the second attaching portion (14) of the fastener (10) is attached in the corresponding aperture (32) by the tab (144) being pressed downwards. The central portion of the strip (16) is abutted the radiator (20) in the slot (220).

The other fastener (10) is located in the other slot (220) of the radiator (20) and attached to the corresponding aperture (32), so that the radiator (20) is tightly fastened on the seat (30).

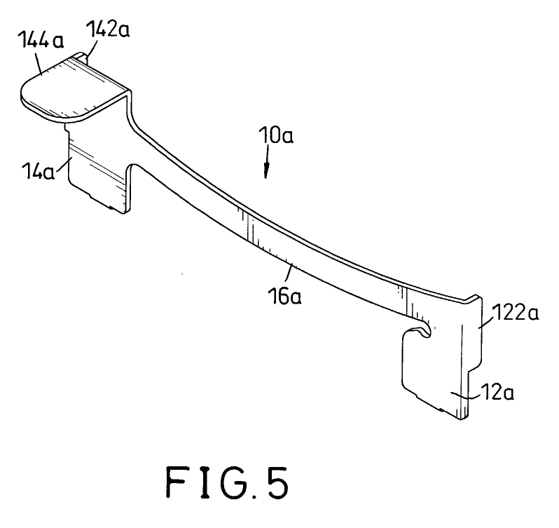

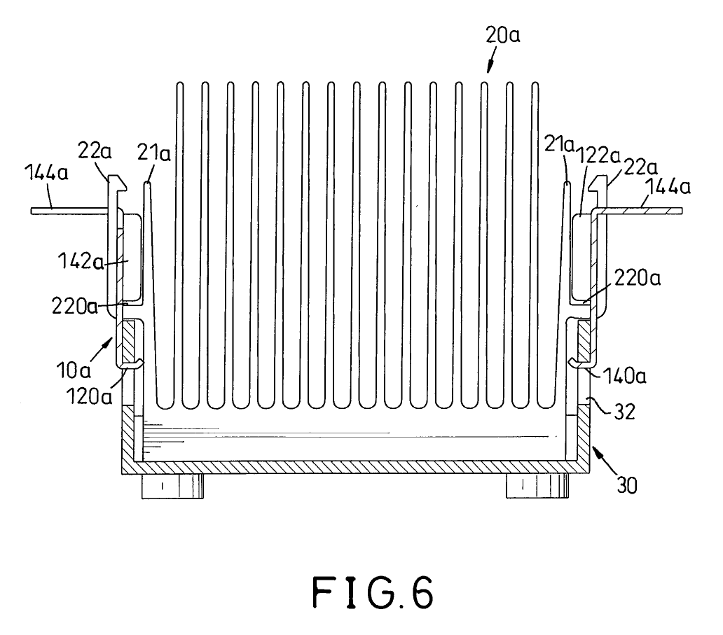

Referring to FIGS. 5-6, in a second embodiment of the invention, the fastener (10a) has a strip (16a), a first attaching portion (12a) formed at a first end of the strip (16a), and a second attaching portion (14a) formed at a second end of the strip (16a). The first attaching portion (12a) has a first hook (120a) formed at a bottom thereof, and a first ear (122a) formed at a side thereof. The second attaching portion (14a) has a second hook (140a) formed at a bottom thereof, and a second ear (142a) formed at a side thereof. A tab (144a) is formed on a top of the second attaching portion (14a). The strip (16a) has a central portion (not numbered) curved downwards from the ends thereof.

In this embodiment, there are no bent portions formed on the strip (16a), and the attaching portions (12a, 14a) and the strip (16a) are in the same surface.

In assembling, the radiator (20a) is first placed on the seat (30). The first hook (120a) of the first attaching portion (12a) of the fastener (10a) is attached in the corresponding aperture (32) and the first ear (122a) is abutted the radiator (20a). The strip (16a) is located in the slot (220a), and the second hook (140a) of the second attaching portion (14a) of the fastener (10a) is attached in the corresponding aperture (32) by the tab (144a) being pressed downwards. The central portion of the strip (16a) is abutted the radiator (20a) in the slot (220a).

The other fastener (10a) is located in the other slot (220a) of the radiator (20a) and attached the corresponding aperture (32), so that the radiator (20a) is tightly fastened on the seat (30).

Therefore, according to the invention, it is very easy and convenient to install the radiator (20) on the radiator seat (30) by the fastener (10).

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A fastener for installing a radiator on a radiator seat, the fastener (10) comprising:
a strip (16) having a central portion curved downwards from two ends thereof;
a first attaching portion (12) formed at a first end of the strip (16), the first attaching portion (12) having a first hook (120) formed at a bottom thereof; and
a second attaching portion (14) formed at a second end of the strip (16), the second attaching portion (14) having a second hook (140) formed at a bottom thereof, and a tab (144) formed on a top of thereof.

2. The fastener as claimed in claim 1, wherein the strip (16) further comprises two bent parts (160) respectively formed at joints between the strip (16) and the attaching portions (12, 14).

3. The fastener as claimed in claim 1, wherein the first attaching portion (12) has a first ear (122) formed at a side thereof; and the second attaching portion (14) has a second ear (142) formed at a side thereof.
